(19) United States
(12) Patent Application Publication
(10) Pub. No.: US 2010/0224920 A1
(43) Pub. Date: Sep. 9, 2010

(54) MAGNETORESISTIVE MEMORY CELL AND METHOD OF MANUFACTURING MEMORY DEVICE INCLUDING THE SAME

(76) Inventor: Seung Hyun LEE, Seoul (KR)

Correspondence Address: IP & T Law Firm PLC, 7700 Little River Turnpike, Suite 207, Annandale, VA, 22003, US

(21) Appl. No.: 12/643,011

(22) Filed: Dec. 21, 2009

(30) Foreign Application Priority Data
Mar. 4, 2009 (KR) 10-2009-0018554

(51) Int. Cl. H01L 29/82; H01L 21/00

(52) U.S. Cl. 257/295; 438/3; 257/421; 257/E21.001; 257/E29.323

(57) ABSTRACT

A magnetoresistive memory cell includes a magnetic tunnel junction element; and a selection transistor, wherein the selection transistor includes a first conductive type semiconductor layer, a gate electrode formed on the first conductive type semiconductor layer with a gate insulation film interposed between the first conductive type semiconductor layer and the gate electrode, and second conductive type first and second diffusion regions formed in the first conductive type semiconductor such that the first and second diffusion regions are spaced apart from each other. The magnetic tunnel junction element includes a free magnetization layer, a fixed magnetization layer, and a tunnel barrier layer interposed between the free magnetization layer and the fixed magnetization layer, and the free magnetization layer of the magnetic tunnel junction element is electrically connected to any one of the first and second diffusion regions of the selection transistor.

This application claims the benefit of Korean Application No. 10-2009-0018554, filed on Mar. 4, 2009, which is incorporated by reference herein in its entirety.

### BACKGROUND OF THE INVENTION

1. Field of the Invention

The present invention relates to magnetic random access memory (MRAM), and, particularly, to a nonvolatile memory device using the change in magnetoresistance.

2. Description of the Related Art

Dynamic random access memory (DRAM), which is a typical memory device, is advantageous in that it can be operated at high speed and can be highly integrated, but is disadvantageous in that data stored therein is lost due to volatility upon turn-off of the power and data must be continuously rerecorded by refreshing the data even during use, thus increasing power use. Further, flash memory, which is characterized by nonvolatility and high integration, is disadvantageous in that its operation speed is low. In contrast to such memory devices, magnetoresistive random access memory (MRAM), which stores information using the difference in magnetoresistance, is advantageous in that it can be highly integrated at the same time as being characterized by nonvolatility and high-speed operation.

Meanwhile, MRAM is referred to as a nonvolatile memory device using the change in magnetoresistance depending on the magnetization direction between ferromagnetic bodies. Currently, as a cell structure mostly employed in MRAM, there is a giant magnetoresistance (GMR) element using a giant magnetoresistance (GMR) effect, a magnetic tunnel junction (MTJ) element using a tunnel magnetoresistance (TMR) effect, or the like. In addition, in order to overcome the disadvantages of the GMR element, there is a spin-valve element in which a ferromagnetic layer is reinforced with a permanent magnet and a soft magnetic layer is employed as a free layer. In particular, since the MTJ element operates at high speed and has low power consumption, it is used as an alternative for the capacitors of DRAM, and thus it can be practically applied to a low-power and high-speed graphic mobile device.

Generally, a magnetoresistive element has low resistance when spin directions (that is, magnetic momentum directions) of two magnetic layers are identical to each other, and has high resistance when the spin directions thereof are opposite to each other. Therefore, bit data can be recorded in a magnetoresistive memory device using the fact that the resistance of a cell is changed depending on the magnetized state of the magnetic layers. Describing MTJ-structured magnetoresistive memory as an example, in an MTJ memory cell having a structure of a first ferromagnetic layer/an insulation layer/a second ferromagnetic layer, when electrons having passed through the first ferromagnetic layer pass through the insulation layer used as a tunneling barrier, the tunneling probability thereof is changed depending on the magnetization direction of the second ferromagnetic layer. That is, when the magnetization directions of the two ferromagnetic layers are parallel to each other, tunneling current becomes highest, and when the magnetization directions thereof are nonparallel to each other, the tunneling current becomes lowest. For example, it may be considered that data ‘1’ (or ‘0’) is recorded when resistance is high and data ‘0’ (or ‘1’) is recorded when the resistance is low. Among the two ferromagnetic layers, one ferromagnetic layer is referred to as a fixed magnetization layer in which its magnetization direction is fixed, and the other ferromagnetic layer is referred to as a free magnetization layer in which its magnetization direction is reversed by an external magnetic field or external current.

Meanwhile, writing methods of an MTJ element may be classified into magnetic field switching methods and current switching methods depending on the method of inducing the magnetization reversal of a free magnetization layer. In particular, the current switching methods are conducted using a spin-transfer torque (STT) phenomenon, and the STT phenomenon is a phenomenon in which spin is transferred to the angular momentum of a ferromagnetic body by the change in angular momentum instantaneously occurring when current passes through the ferromagnetic bod. In the case where this current switching method is applied to the MTJ element, when electrons flow from a fixed magnetization layer to a free magnetization layer, torque for aligning the magnetization direction of the free magnetization layer to the magnetization direction of the fixed magnetization layer is transferred to the MTJ element by the flow of spin-aligned electrons, so that the magnetization direction of the free magnetization layer becomes identical to the magnetization direction of the fixed magnetization layer. Conversely, when electrons flow from a free magnetization layer to a fixed magnetization layer, a spin accumulation phenomenon occurs on the boundary between the free magnetization layer and the fixed magnetization layer, so that the magnetization direction of the free magnetization layer becomes opposite to the magnetization direction of the fixed magnetization layer.

Generally, in a magnetoresistive memory device using a current switching method, a memory cell for storing information includes a magnetic tunnel junction element and a selection transistor which selects the magnetic tunnel junction element and enables the selected magnetic tunnel junction element to record and read data. Here, in order to record the information stored in the magnetoresistive memory device, very high current must flow in both directions through the magnetic tunnel junction. In this case, current intensity required to change the magnetization state of the magnetic tunnel junction element from an equilibrium state to a semi-equilibrium state is higher than current intensity required to change the magnetization state of the magnetic tunnel junction element from a semi-equilibrium state to an equilibrium state. Due to the asymmetric property of the switching current, when the fixed magnetization layer of the magnetic tunnel junction element is connected to the selection transistor, the driving capability of the selection transistor is required to be high. However, in an ultra-miniature transistor required to realize highly-integrated memory, it is difficult to drive high current to such a degree that information can be recorded in the magnetic tunnel junction element.

### SUMMARY OF THE INVENTION

In order to realize a highly-integrated magnetoresistive memory device, a selection transistor having high current driving capability for the magnetization reversal of a magnetic tunnel junction element may be required to be fabricated. However, since the current driving capability of the selection transistor is proportional to the area used to form the selection transistor, the magnetization reversal current density of the magnetic tunnel junction element may be decreased in order to realize the highly-integrated magnetoresistive memory device. In an embodiment of the present invention, when the magnetization direction of the magnetic tunnel junction element is reversed using a current switching method, based on the current asymmetric property that current intensity required to change the magnetization state of the magnetic tunnel junction element from an equilibrium state to a semi-equilibrium state is different from the current intensity required to change the magnetization state of the magnetic tunnel junction element from a semi-equilibrium state to an equilibrium state, it was found that, at the time of performing a write operation from an equilibrium state to a semi-equilibrium state, the current obtained by connecting a free magnetization layer of the magnetic tunnel junction element in series to the selection transistor is higher that the current obtained by connecting a fixed magnetization layer of the magnetic tunnel junction element in series to the selection transistor. Based on this finding, the magnetic tunnel junction element can be driven even by a selection transistor having a relatively small formation area. Accordingly, an object of an embodiment of the present invention is to realize a highly-integrated magnetoresistive memory device.

An aspect of an embodiment of the present invention provides a magnetoresistive memory cell, including: a magnetic tunnel junction element; and a selection transistor. In the magnetoresistive memory cell, the selection transistor may include a first conductive type semiconductor layer, a gate electrode formed on the first conductive type semiconductor layer with a gate insulation film interposed between the first conductive type semiconductor layer and the gate electrode, and second conductive type first and second diffusion regions formed in the first conductive type semiconductor such that the first and second diffusion regions are spaced apart from each other. Further, the magnetic tunnel junction element may include a free magnetization layer, a fixed magnetization layer, and a tunnel barrier layer interposed between the free magnetization layer and the fixed magnetization layer. Further, the free magnetization layer of the magnetic tunnel junction element may be electrically connected to one of the first and second diffusion regions of the selection transistor.

Another aspect of an embodiment of the present invention provides a magnetoresistive memory cell array, including: a selection transistor including a first conductive type semiconductor layer, a gate electrode formed on the first conductive type semiconductor layer with a gate insulation film interposed between the first conductive type semiconductor layer and the gate electrode, and second conductive type first and second diffusion regions formed in the first conductive type semiconductor such that the first and second diffusion regions are spaced apart from each other; a magnetic tunnel junction element including a free magnetization layer, a fixed magnetization layer, and a tunnel barrier layer interposed between the free magnetization layer and the fixed magnetization layer; a word line electrically connected to the gate electrode of the selection transistor; a bit line electrically connected to the fixed magnetization layer of the magnetic tunnel junction element; and a source line electrically connected to the second diffusion region of the selection transistor. Here, the fixed magnetization layer of the magnetic tunnel junction element may be electrically connected to the bit line, and the second diffusion region of the selection transistor may be electrically connected to the source line.

Still another aspect of the present invention provides a method of manufacturing a magnetoresistive memory device, comprising the steps of: forming a selection transistor in a semiconductor substrate, including a first conductive type semiconductor layer, a gate electrode formed on the first conductive type semiconductor layer with a gate insulation film interposed between the first conductive type semiconductor layer and the gate electrode, and second conductive type first and second diffusion regions formed in the first conductive type semiconductor such that the first and second diffusion regions are spaced apart from each other; forming a first interlayer dielectric film over the semiconductor substrate in which the selection transistor has been formed; forming a plurality of contact plugs respectively connected to the first and second diffusion regions after partially removing the first interlayer dielectric film; forming a source line electrically connected with the contact plug connected to the second diffusion region, and a bit line electrically insulated from the source line; forming a magnetic tunnel junction element including a fixed magnetization layer electrically connected with the bit line, a tunnel barrier layer formed on the fixed magnetization layer, and a free magnetization layer formed on the tunnel barrier layer; and forming a contact plug and a metal line through which the free magnetization layer of the magnetic tunnel junction element is electrically connected with the contact plug connected to the first diffusion region.

Further, still another aspect of an embodiment of the present invention provides a method of manufacturing a magnetoresistive memory device, comprising the steps of: forming a selection transistor in a semiconductor substrate, including a first conductive type semiconductor layer, a gate electrode formed on the first conductive type semiconductor layer with a gate insulation film interposed between the first conductive type semiconductor layer and the gate electrode, and second conductive type first and second diffusion regions formed in the first conductive type semiconductor such that the first and second diffusion regions are spaced apart from each other; forming a first interlayer dielectric film over the semiconductor substrate in which the selection transistor has been formed; forming a plurality of contact plugs respectively connected to the first and second diffusion regions after partially removing the first interlayer dielectric film; forming a source line electrically connected with the contact plug connected to the second diffusion region; forming a magnetic tunnel junction element including a free magnetization layer electrically connected with the contact plug connected to the first diffusion region, a tunnel barrier layer formed on the free magnetization layer, and a fixed magnetization layer formed on the tunnel barrier layer; and forming a bit line electrically connected to the fixed magnetization layer of the magnetic tunnel junction element.

### BRIEF DESCRIPTION OF THE DRAWINGS

The above and other objects, features and advantages of the present invention will be more clearly understood from the following detailed description taken in conjunction with the accompanying drawings, in which:

FIGS. 1 to 5 are sectional views showing a method of manufacturing a magnetoresistive memory device according to a first embodiment of the present invention; and

FIGS. 6 to 9 are sectional views showing a method of manufacturing a magnetoresistive memory device according to a second embodiment of the present invention.

### DESCRIPTION OF THE PREFERRED EMBODIMENTS

Hereinafter, preferred embodiments of the present invention will be described in detail with reference to the attached drawings. Throughout the accompanying drawings, the same reference numerals are used to designate the same or similar components, and redundant descriptions thereof are omitted. Further, a detailed description of related art which would obscure the gist of the present invention will be omitted from the description of the present invention.

[Structure of a Memory Cell]

A magnetoresistive memory cell according to an embodiment of the present invention includes a magnetic tunnel junction element and a selection transistor. The selection transistor may be a metal-oxide semiconductor (MOS) transistor including a first conductive type semiconductor layer, a gate electrode formed by interposing a gate insulation film in the upper portion of the first conductive type semiconductor layer, and second conductive type first and second diffusion regions formed in the first conductive type semiconductor layer such that the second conductive type first and second diffusion regions are spaced apart from each other. Here, the first conductive type and the second conductive type are opposite to each other. For example, an N-type dopant is implanted into a P-type semiconductor layer, which is a first conductive type semiconductor layer, thereby forming second conductive type first and second diffusion regions. The first and second diffusion regions function as sources and drains of the MOS transistor, and are formed such that the first and second diffusion regions are spaced apart from each other in the lower portion of the gate electrode.

Further, the magnetic tunnel junction element may include a free magnetization layer, a fixed magnetization layer, and a tunnel barrier layer interposed between the free magnetization layer and the fixed magnetization layer. Here, each of the free magnetization layer and the fixed magnetization layer may be made of Co, Fe, Ni or an alloy thereof, for example, an intermetallic compound such as CoFe, CoFeB, NiFe or the like. Further, the tunnel barrier layer interposed between the free magnetization layer and the fixed magnetization layer may be made of a metal or nonmetal oxide, for example, an oxide such as AlO, TiO, MgO, HfO, CuO, NiO, CoO or the like. Moreover, the fixed magnetization layer may include an antiferromagnetic layer made of MnPt, MnIr or the like, and, owing to the antiferromagnetic layer, the magnetization reversal of the fixed magnetization layer does not occur, and the magnetization reversal of only the free magnetization layer occurs. Furthermore, each of the free magnetization layer and the fixed magnetization layer may be formed into a synthetic antiferromagnetic (SAF) layer in which a nonmagnetic layer, such as a Ru layer, is interposed between two magnetic layers.

Meanwhile, according to the magnetoresistive memory cell of an embodiment of the present invention, a write operation may be performed by a current switching method, and, in this case, the magnetization direction of the free magnetization layer of the magnetic tunnel junction element may be reversed by the current switching method. Further, according to the magnetoresistive memory cell of an embodiment of the present invention, the free magnetization layer of the magnetic tunnel junction element may be connected in series to the selection transistor. For example, the free magnetization layer of the magnetic tunnel junction element is connected to a drain region (that is, a second conductive type diffusion region) of the selection transistor. In this case, current intensity required to change the magnetization state of the magnetic tunnel junction element from an equilibrium state to a semi-equilibrium state is higher than the current intensity required to change the magnetization state of the magnetic tunnel junction element from a semi-equilibrium state to an equilibrium state. Therefore, owing to the asymmetric property of switching current, when the fixed magnetization layer of the magnetic tunnel junction element is connected to the selection transistor, the selection transistor is required to have higher driving capability. However, according to an embodiment of the present invention, when the free magnetization layer of the magnetic tunnel junction element is connected to the selection transistor, the magnetization state of the magnetic tunnel junction element may be changed even by a selection transistor having lower driving capability. Accordingly, since the limitation in the driving capability of the selection transistor necessary for operating the magnetoresistive memory cell is relaxed, a highly-integrated magnetic memory device, which may be operated even by a selection transistor having a smaller formation area, may be manufactured.

[Structure of a Memory Cell Array]

Unit memory cells constituting a magnetoresistive memory cell array according to an embodiment of the present invention are formed of the above-mentioned magnetoresistive memory cells. Here, data are stored in the respective unit memory cells and read from the respective unit memory cells through a word line electrically connected to a gate electrode of a selection transistor, a bit line electrically connected to a fixed magnetization layer of a magnetic tunnel junction element and a source line electrically connected to any one of first and second diffusion regions of the selection transistor.

The magnetoresistive memory cell array according to an embodiment of the present invention may be configured such that gate electrodes of the respective selection transistors of the plurality of unit memory cells formed in active regions electrically separated from each other are connected to one word line. A method of manufacturing the magnetoresistive memory cell array according to the present invention will be described in more detail with the reference to the following embodiments.

Meanwhile, in the magnetoresistive memory cell array according to an embodiment of the present invention, the drain of a selection transistor is directly connected to a free magnetization layer and may thus be connected to a bit line via a magnetic tunnel junction element, and the source of the selection transistor may be directly connected to a source line. In this case, when the write operation of the magnetoresistive memory cell array is performed using a current switching method, the magnetic tunnel junction element may be switched even by a selection transistor (that is, an MOS transistor having smaller formation area) having lower current driving capability. Thus, the magnetoresistive memory cell array may be highly integrated.

[Method of Manufacturing a Magnetoresistive Memory Device]

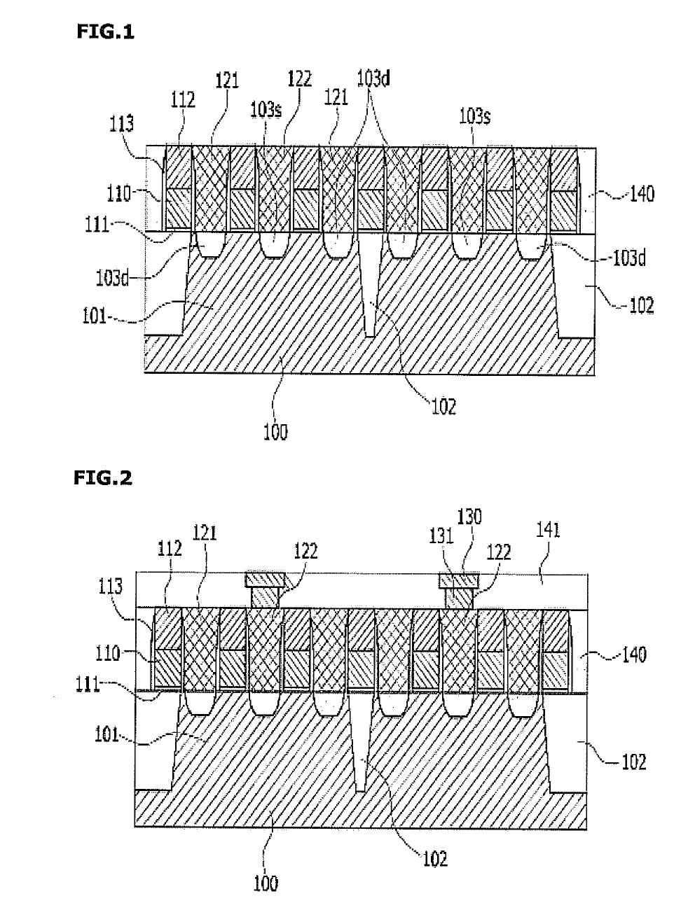

Hereinafter, a method of manufacturing a magnetoresistive memory device provided with a memory cell array including magnetoresistive memory cells according to an embodiment of the present invention will be described in detail with reference to FIGS. 1 to 5.

First, referring to FIG. 1, a semiconductor substrate 100 is provided with first conductive type semiconductor layers 101, each of which is an active region in which a plurality of memory cells is to be formed. For example, two memory cells may be formed in one semiconductor layer 101, and each of the semiconductor layers 101 is an active region in which MOS transistors are to be formed, and is electrically insulated from an adjacent semiconductor layer 101 by a device separation membrane 102.

A gate insulation film 111 is formed on each of the semiconductor layers 101 to form gate electrodes 110. First and second diffusion regions 103d and 103s spaced apart from each other are formed in each of the semiconductor layers 101 by ion-implanting a second conductive type dopant, which is a dopant opposite to a first conductive type dopant, using the gate electrodes 110 as a mask. Here, the gate electrodes 110 may function as a word line, and may be shared with a selection transistor of memory cells formed in the adjacent semiconductor layer 101. Further, each of the gate electrodes 110 may be made of a polysilicon film, may be formed thereon with a protection film 112, and may be formed on the side wall thereof with an insulation spacer 113. A selection transistor including the gate electrodes 110 and the first and second diffusion regions 103d and 103s is formed, and then a first interlayer dielectric film 140 is formed over the semiconductor substrate 100. Subsequently, a plurality of landing contact plugs 121 and 122, which pass through the first interlayer dielectric film 140 and are electrically connected to the first and second diffusion regions 103d and 103s, are formed using a self-aligned contact process.

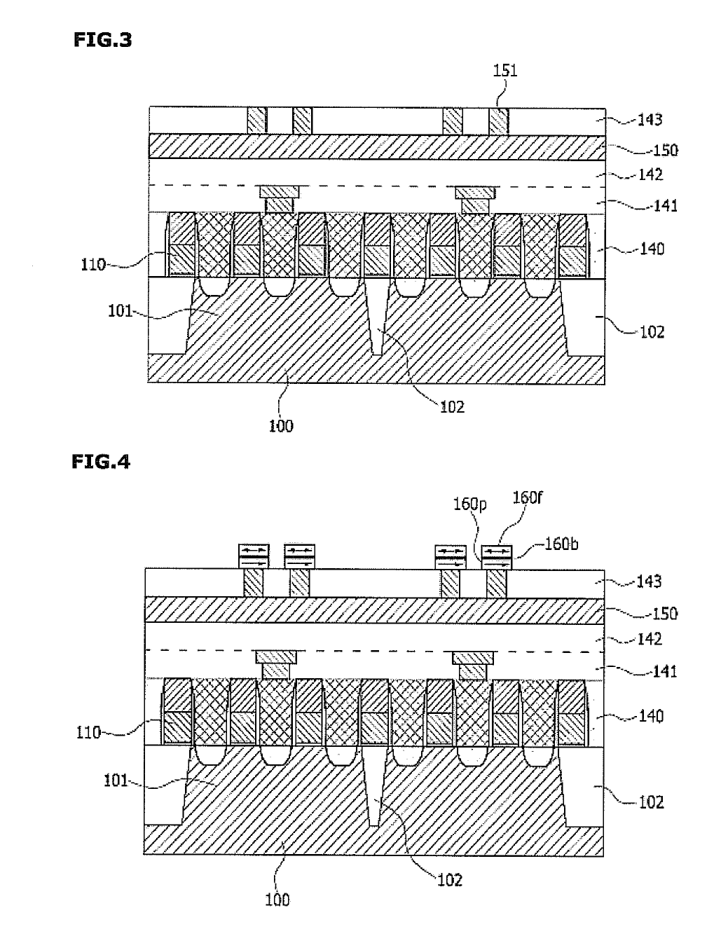

Next, as shown in FIG. 2, a second dielectric film 141 is formed on the first dielectric film 140, and then source line contacts 131, which are electrically connected with the landing contact plugs 122 connected to second diffusion regions 103s, and source lines 130 are formed in the second dielectric film 141 using a photo-etching process and a metal processing process. Subsequently, as shown in FIG. 3, a third dielectric film 142 is formed on the second dielectric film 141, and then a bit line is formed on the third dielectric film 142 such that the bit line is electrically insulated from the source lines 130. Subsequently, a fourth dielectric film 143 is formed on the bit line 150, and then contact plugs 151, which are electrically connected with a magnetic tunnel junction element in subsequent processes, are formed in the fourth dielectric film 143.

Thereafter, as shown in FIG. 4, magnetic tunnel junction elements electrically connected with the bit line 150 through contact plugs 151 are formed on the fourth dielectric film 143. In this case, each of the magnetic tunnel junction elements is formed by sequentially laminating a fixed magnetization layer 160p, a tunnel barrier layer 160b and a free magnetization layer 160f. Here, the fixed magnetization layer 160p is formed to be electrically connected with the contact plug 151.

Subsequently, as shown in FIG. 5, a fifth interlayer dielectric layer 144 is formed on the fourth dielectric film 143, and then contact plugs 171 and metal lines 172 are formed in the fifth interlayer dielectric layer 144 such that the free magnetization layer 160f of the magnetic tunnel junction element is electrically connected with the contact plug 121 connected to the first diffusion region 103d.

Through the above-mentioned method, a magnetoresistive memory cell array having a structure in which a free magnetization layer 160f of a magnetic tunnel junction element is directly connected to a drain 103d of a selection transistor may be formed.

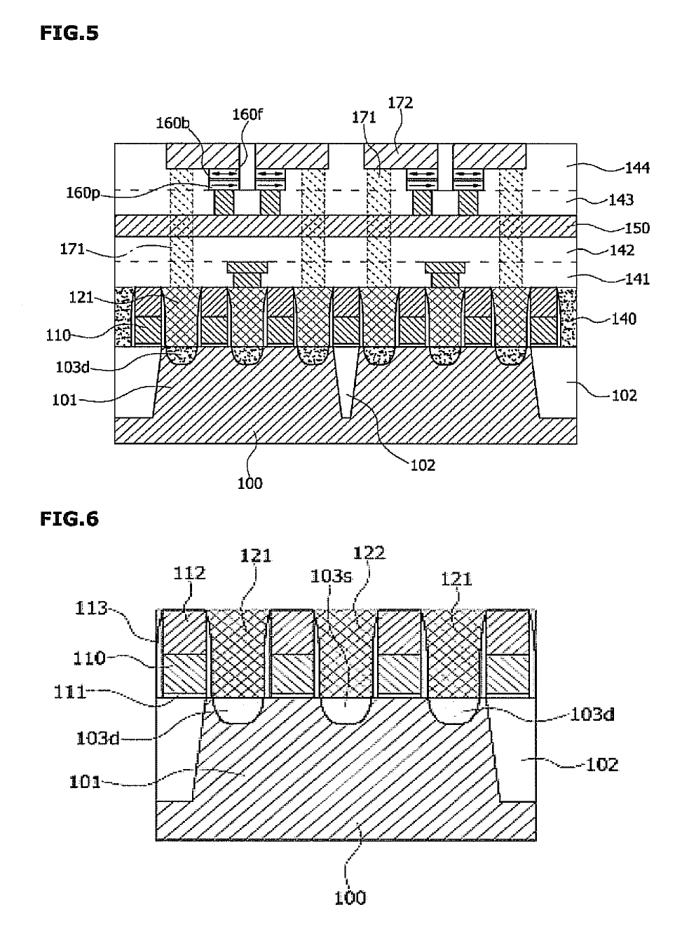

FIGS. 6 to 9 show a method of manufacturing a magnetoresistive memory device according to another embodiment of the present invention. Here, since the method of manufacturing a magnetoresistive memory device shown in FIG. 6 is actually identical with that described in the above-mentioned embodiment, the detailed description thereof is unnecessary and is thus omitted.

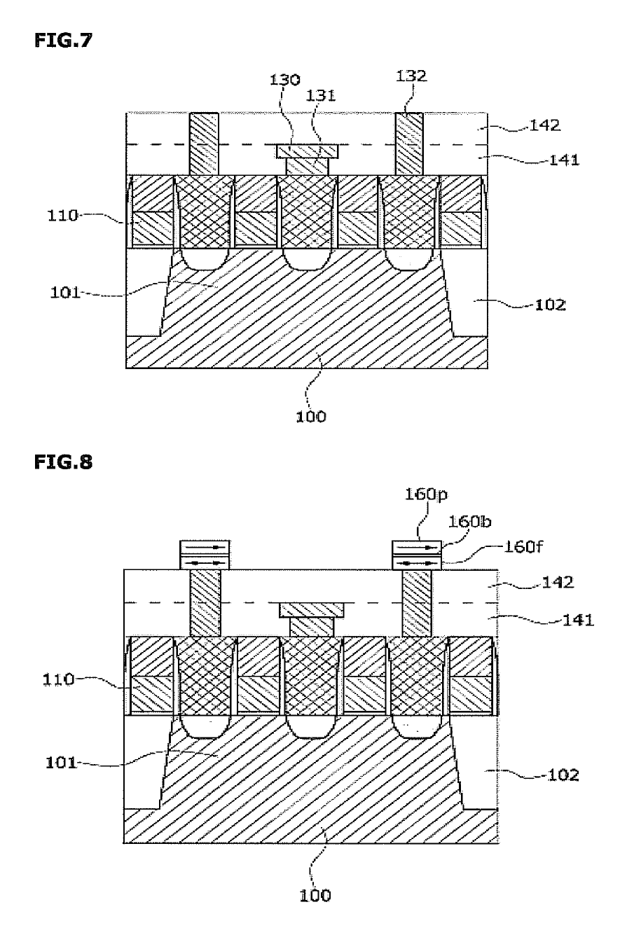

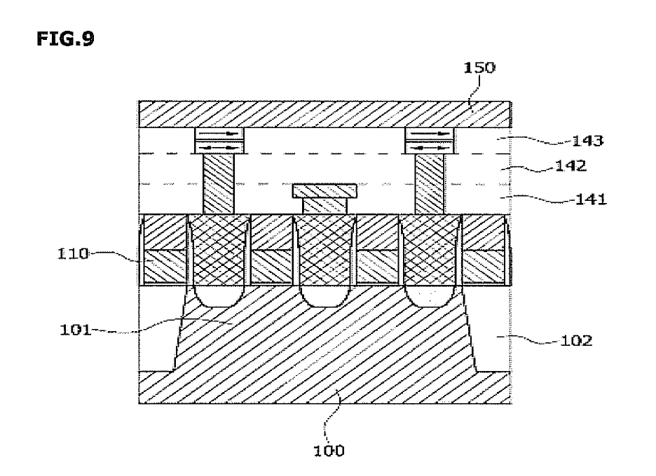

Referring to FIG. 7, a first dielectric film 141 is formed, and then a source line contact 131, which is electrically connected with the landing contact plug 122 connected to second diffusion region 103s, and a source line 130 are formed in the first dielectric film 141 using a photo-etching process and a metal processing process. Subsequently, a second dielectric film 142 is formed on the first dielectric film 141, and then contact plugs 132, which are electrically connected with the contact plugs 121 connected to the first diffusion regions 103d, are formed in the first and second dielectric films 141 and 142. Subsequently, as shown in FIG. 8, a free magnetization layer 160f electrically connected with the contact plug 132 is formed on the second dielectric film 142, and then a tunnel barrier layer 160b and a fixed magnetization layer 160p are sequentially laminated on the free magnetization layer 160f, thus forming a magnetic tunnel junction element. Subsequently, as shown in FIG. 9, a third interlayer dielectric film 143 is formed on the second dielectric film 142, and then a bit line 150 electrically connected to the fixed magnetization layer 160p is formed on the third interlayer dielectric film 143 using a photo-etching process and a metal processing process.

As described above, according to this embodiment of the present invention, the formation area of a selection transistor may be minimized through a magnetoresistive memory cell structure configured such that a free magnetization layer of a magnetic tunnel junction element is connected in series to the selection transistor without decreasing the magnetization reversal current density of the magnetic tunnel junction element, and thus the magnetoresistive memory device may be highly-integrated in an easy manner.

Although the preferred embodiments of the present invention have been disclosed for illustrative purposes, those skilled in the art will appreciate that various modifications, additions and substitutions are possible, without departing from the scope and spirit of the invention as disclosed in the accompanying claims. It should also be understood that the foregoing relates to only the scope of the invention is defined by the appended claims rather than by the description preceding them, and all changes that fall within the meets and bounds of the claims, or the equivalence of such metes and bounds are therefore intended to be embraced by the claims.

What is claimed is:

1. A magnetoresistive memory cell, comprising:
a selection transistor including a first conductive type semiconductor layer, a gate electrode formed on the first conductive type semiconductor layer with a gate insulation film interposed between the first conductive type semiconductor layer and the gate electrode, and second conductive type first and second diffusion regions formed in the first conductive type semiconductor such that the first and second diffusion regions are spaced apart from each other; and
a magnetic tunnel junction element including a free magnetization layer, a fixed magnetization layer, and a tunnel barrier layer interposed between the free magnetization layer and the fixed magnetization layer,
wherein the free magnetization layer of the magnetic tunnel junction element is electrically connected to one of the first and second diffusion regions of the selection transistor.

2. The magnetoresistive memory cell according to claim 1, wherein a magnetization direction of the free magnetization layer of the magnetic tunnel junction element is reversed by a current switching method.

3. The magnetoresistive memory cell according to claim 1, wherein the magnetic tunnel junction element is positioned above the selection transistor and is connected to the selection transistor through a contact plug formed over the first conductive type semiconductor layer.

4. The magnetoresistive memory cell according to claim 3, wherein the contact plug is in electrical contact with one of the second conductive type first and second diffusion regions.

5. A magnetoresistive memory cell array, comprising:
a selection transistor including a first conductive type semiconductor layer, a gate electrode formed on the first conductive type semiconductor layer with a gate insulation film interposed between the first conductive type semiconductor layer and the gate electrode, and second conductive type first and second diffusion regions formed in the first conductive type semiconductor such that the first and second diffusion regions are spaced apart from each other;
a magnetic tunnel junction element including a free magnetization layer, a fixed magnetization layer, and a tunnel barrier layer interposed between the free magnetization layer and the fixed magnetization layer;
a word line electrically connected to the gate electrode of the selection transistor;
a bit line electrically connected to the fixed magnetization layer of the magnetic tunnel junction element; and
a source line electrically connected to the second diffusion region of the selection transistor.

6. The magnetoresistive memory cell array according to claim 5, wherein a magnetization direction of the free magnetization layer of the magnetic tunnel junction element is reversed by a current switching method.

7. The magnetoresistive memory cell array according to claim 5, wherein the magnetic tunnel junction element is positioned above the selection transistor and is connected to the selection transistor through a contact plug formed over the first conductive type semiconductor layer.

8. The magnetoresistive memory cell array according to claim 7, wherein the contact plug is in electrical contact with one of the second conductive type first and second diffusion regions,

9. A method of manufacturing a magnetoresistive memory device, comprising the steps of:
forming a selection transistor in a semiconductor substrate, including a first conductive type semiconductor layer, a gate electrode formed on the first conductive type semiconductor layer with a gate insulation film interposed between the first conductive type semiconductor layer and the gate electrode, and second conductive type first and second diffusion regions formed in the first conductive type semiconductor such that the first and second diffusion regions are spaced apart from each other;
forming a first interlayer dielectric film over the semiconductor substrate in which the selection transistor has been formed;
forming a plurality of contact plugs respectively connected to the first and second diffusion regions after partially removing the first interlayer dielectric film;
forming a source line electrically connected with the contact plug connected to the second diffusion region, and a bit line electrically insulated from the source line;
forming a magnetic tunnel junction element including a fixed magnetization layer electrically connected with the bit line, a tunnel barrier layer formed on the fixed magnetization layer, and a free magnetization layer formed on the tunnel barrier layer; and
forming a contact plug and a metal line through which the free magnetization layer of the magnetic tunnel junction element is electrically connected with the contact plug connected to the first diffusion region.

10. The method according to claim 9, wherein forming the magnetic tunnel junction element further comprises forming the magnetic tunnel junction element to be positioned above the selection transistor and to be connected to the selection transistor through a contact plug formed over the first conductive type semiconductor layer.

11. The method according to claim 10, wherein the contact plug is in electrical contact with one of the second conductive type first and second diffusion regions.

12. A method of manufacturing a magnetoresistive memory device, comprising the steps of:
forming a selection transistor in a semiconductor substrate, including a first conductive type semiconductor layer, a gate electrode formed on the first conductive type semiconductor layer with a gate insulation film interposed between the first conductive type semiconductor layer and the gate electrode, and second conductive type first and second diffusion regions formed in the first conductive type semiconductor such that the first and second diffusion regions are spaced apart from each other;
forming a first interlayer dielectric film over the semiconductor substrate in which the selection transistor has been formed;
forming a plurality of contact plugs respectively connected to the first and second diffusion regions after partially removing the first interlayer dielectric film;
forming a source line electrically connected with the contact plug connected to the second diffusion region;
forming a magnetic tunnel junction element including a free magnetization layer electrically connected with the contact plug connected to the first diffusion region, a tunnel barrier layer formed on the free magnetization layer, and a fixed magnetization layer formed on the tunnel barrier layer; and
forming a bit line electrically connected to the fixed magnetization layer of the magnetic tunnel junction element.

13. The method according to claim 12, wherein forming the magnetic tunnel junction element further comprises forming the magnetic tunnel junction element to be positioned above the selection transistor and to be connected to the selection transistor through a contact plug formed over the first conductive type semiconductor layer.

14. The method according to claim 13, wherein the contact plug is in electrical contact with one of the second conductive type first and second diffusion regions.
